(19) United States
(12) Patent Application Publication
(10) Pub. No.: US 2023/0397370 A1
(43) Pub. Date: Dec. 7, 2023

(54) Wearable Electronic Device with Thermal Energy Dissipation System and Corresponding Methods

(71) Applicant: Motorola Mobility LLC, Chicago, IL (US)

(72) Inventors: Alberto R. Cavallaro, Northbrook, IL (US); Maninder S Sehmbey, Hoffman Estates, IL (US)

(21) Appl. No.: 17/834,733

(22) Filed: Jun. 7, 2022

(51) Int. Cl. H05K 7/20; H05K 1/02

(52) U.S. Cl. CPC H05K 7/20336; H05K 1/0203; H05K 7/2039

(57) ABSTRACT

A wearable electronic device includes a device housing. Heat generating electronics are situated within the device housing. The device housing includes a reservoir of evaporative fluid. A wicking element engages the reservoir of evaporative fluid to draw the evaporative fluid from the reservoir of evaporative fluid through the wicking element to remove thermal energy from the heat generating electronics.

### BACKGROUND

### Technical Field

This disclosure relates generally to wearable electronic devices, and more particularly to wearable electronic devices carrying heat generating electronics.

### Background Art

Portable electronic devices, such as smartphones, tablet computers, and wearable electronic devices, are becoming ubiquitous in modern society. Many people today own a smart phone or other wireless communication device with which they communicate with friends, workers, and family, manage calendars, purchase goods and services, listen to music, watch videos, play games, and surf the Internet.

As the technology associated with these devices develops, users frequently demand for lighter and thinner devices. Housing walls get thinner, as does the available volume within the device. At the same time, the small yet powerful processors within the device can generate large amounts of thermal energy when operating at maximum capacity. Excess heat can compromise the reliability of interior components, as well as make the device less than comfortable to handle. It would be advantageous to have an improved thermal management system for portable electronic devices.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present disclosure.

FIG. 1 illustrates one explanatory wearable electronic device in accordance with one or more embodiments of the disclosure.

FIG. 2 illustrates a perspective view of one explanatory wearable electronic device in accordance with one or more embodiments of the disclosure.

FIG. 3 illustrates a rear elevation view of one explanatory wearable electronic device in accordance with one or more embodiments of the disclosure.

FIG. 4 illustrates a schematic diagram of one explanatory wearable electronic device in accordance with one or more embodiments of the disclosure.

FIG. 5 illustrates a front elevation view of one explanatory anterior pendant in accordance with one or more embodiments of the disclosure.

FIG. 6 illustrates a side elevation view of one explanatory anterior pendant in accordance with one or more embodiments of the disclosure.

FIG. 7 illustrates one explanatory anterior pendant in accordance with one or more embodiments of the disclosure.

FIG. 8 illustrates a top plan view of elements of one explanatory thermal management system suitable for incorporation into the anterior pendant of FIG. 7.

FIG. 9 illustrates a side elevation view of elements of one explanatory thermal management system suitable for incorporation into the anterior pendant of FIG. 7.

FIG. 10 illustrates one explanatory electronic device in accordance with embodiments of the disclosure in use.

FIG. 11 illustrates one explanatory method in accordance with one or more embodiments of the disclosure.

FIG. 12 illustrates various embodiments of the disclosure.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present disclosure.

### DETAILED DESCRIPTION OF THE DRAWINGS

Before describing in detail embodiments that are in accordance with the present disclosure, it should be observed that the embodiments reside primarily in combinations of method steps and apparatus components related to a wearable electronic device that includes a device housing containing heat generating electronics, a reservoir of evaporative fluid, and a wicking element engaging the reservoir of evaporative fluid to draw the evaporative fluid from the reservoir through the wicking element to remove thermal energy from the heat generating electronics. Alternate implementations are included, and it will be clear that functions may be executed out of order from that shown or discussed, including substantially concurrently or in reverse order, depending on the functionality involved.

Accordingly, the apparatus components and method steps have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein. It is expected that one of ordinary skill, notwithstanding possibly significant effort and many design choices motivated by, for example, available time, current technology, and economic considerations, when guided by the concepts and principles disclosed herein will be readily capable of generating such methods and systems with minimal experimentation.

Embodiments of the disclosure do not recite the implementation of any commonplace business method aimed at processing business information, nor do they apply a known business process to the particular technological environment of the Internet. Moreover, embodiments of the disclosure do not create or alter contractual relations using generic computer functions and conventional network operations. Quite to the contrary, embodiments of the disclosure employ methods that, when applied to electronic device and/or user interface technology, improve the functioning of the electronic device itself by and improving the overall user experience to overcome problems specifically arising in the realm of the technology associated with electronic device user interaction.

Embodiments of the disclosure are now described in detail. Referring to the drawings, like numbers indicate like parts throughout the views. As used in the description herein and throughout the claims, the following terms take the meanings explicitly associated herein, unless the context clearly dictates otherwise: the meaning of “a,” “an,” and “the” includes plural reference, the meaning of “in” includes “in” and “on.” Relational terms such as first and second, top and bottom, and the like may be used solely to distinguish one entity or action from another entity or action without necessarily requiring or implying any actual such relationship or order between such entities or actions.

As used herein, components may be “operatively coupled” when information can be sent between such components, even though there may be one or more intermediate or intervening components between, or along the connection path. The terms “substantially”, “essentially”, “approximately”, “about,” or any other version thereof, are defined as being close to as understood by one of ordinary skill in the art, and in one non-limiting embodiment the term is defined to be within ten percent, in another embodiment within five percent, in another embodiment within one percent and in another embodiment within one-half percent. The term “coupled” as used herein is defined as connected, although not necessarily directly and not necessarily mechanically. Also, reference designators shown herein in parenthesis indicate components shown in a figure other than the one in discussion. For example, talking about a device (10) while discussing figure A would refer to an element, 10, shown in figure other than figure A.

Embodiments of the disclosure contemplate that processors and other components disposed within wearable electronic devices, which tend to be quite small and are frequently worn with their device housings abutting a wearer's skin, can generate a lot of heat. Moreover, these components tend to be very small. Thus, while the amount of heat generated may not be extreme compared to, say, an oven or furnace, the fact that the heat is concentrated in a small location that may be adjacent to or touching a user's skin makes it problematic. For example, a central processor operating in a wearable electronic device at a maximum level may generate nine watts. If this heat is not dissipated, it can cause damage to the die, surrounding components, or other circuits. Moreover, it can make the wearable electronic device less than comfortable to handle.

For this reason, some manufacturers limit output power of microprocessors and other high output power components in wearable electronic devices. A manufacturer may limit the maximum output power to be generated for a predefined time such as thirty seconds or less. A maximum output power of nine watts might be scaled back to something on the order of four watts after thirty seconds of full performance operation for instance. This prevents damage to the die of the processor or other semiconductor component, as well as protecting the battery chemistry from compromised reliability. The reduction in power also prevents the housing of the device from exceeding the ambient temperature by more than a few degrees centigrade.

The accompanying reduction in performance comes at a cost, namely, that the speed and number of cores in the processor is reduced, thereby causing complex computational tasks to take longer. The user experience is reduced when the device seems to operate slower, despite having the “latest and greatest” processor inside.

The thermal energy problem is especially problematic in electronic devices worn around the neck. When a wearable electronic device such as an augmented reality neckband, virtual reality neckband, or audio output neckband includes a device housing and a neck strap, the amount of thermal energy that can be dissipated from the surface of the device housing is somewhat limited. Prior art attempts to solve the problem include incorporating thermally conductive layers within the device housing in an attempt to spread the thermal energy over a larger area in an effort to dissipate through radiation. Such solutions have only limited success because dissipation through radiation is limited to the size of the device housing.

Embodiments of the disclosure advantageously provide a solution to this problem by providing a wearable electronic device that includes a device housing that has a reservoir of evaporative fluid. A wicking element engages the reservoir of evaporative fluid to draw the evaporative fluid from the reservoir through the wicking element to remove the thermal energy from the heat generating electronics. A fluid reservoir replenishment port is provided to allow the reservoir to be refilled with evaporative fluid.

Embodiments of the disclosure are well suited for electronic devices such as those used in gaming applications. Since these applications may require large amounts of processing power, the processors and other components of such electronic devices can get warm. By providing the wicking element and the reservoir of evaporative fluid, evaporative cooling can keep these electronic devices cool, thereby allowing the processors and other components to run more optimally. A gamer may charge the electronic device and refill the reservoir of evaporative fluid with evaporative fluid between uses. The gamer may then use the electronic device for a period of time, with evaporation of the evaporative fluid allowing the electronic device to stay cool. Upon pausing the game, the process can be repeated with the electronic device being charged and the reservoir of evaporative fluid refilled with evaporative fluid. The wicking element can optionally be replaced as well.

Accordingly, embodiments of the disclosure provide a portable electronic device that includes a wicking element and a reservoir of evaporative fluid that is used to dissipate thermal energy generated by heat generating electronics situated within a device housing of the electronic device. The inclusion of a fluid reservoir replenishment port allows the reservoir of evaporative fluid to be replenished with evaporative fluid.

In one or more embodiments, the wicking element spans a major surface of the device housing of the electronic device. Illustrating by example, in one or more embodiments the wicking element abuts and spans an exterior major surface of the device housing. Additional devices, such as a vapor chamber, can be included in the device housing to aid in transferring the thermal energy from the heat generating electronics to the wicking element. In one or more embodiments, a perforated wicking element retention device is placed over the wicking element to retain the wicking element against the major surface of the electronic device while allowing the evaporative fluid to evaporate to cool the electronic device.

Embodiments of the disclosure contemplate that evaporative cooling dissipates significant amounts of thermal energy due to the fact that the amount of thermal energy dissipated is the product of the mass flux and the latent heat of the evaporative fluid. The latent heat is a very large intensive property, thereby enabling large thermal energy dissipation. Using a convection mass transfer coefficient approach as a function of vapor pressure and density in a dry room, one can estimate that an electronic device having a major surface measuring five centimeters by five centimeters with a thin film wicking element can dissipate on the order of 6.7 Watts.

The other term in the calculation, the mass flux, requires a supply of evaporative fluid. In specific applications for portable electronic devices, the use case is relatively short, and it is possible to replenish the reservoir of evaporative fluid. An example of such an application is a virtual gaming or metaverse experience that may last on the order of two hours. Once the experience is finished, the electronic device can be returned for charging the battery and replenishing the reservoir of evaporative fluid as previously described.

If half of 6.7 Watts can be dissipated via natural convection and radiation, the evaporative cooling provided by embodiments of the disclosure when the evaporative fluid evaporates from the wicking element can dissipate the remainder. Illustrating by example, a 3.35-Watt dissipation would require 0.35 ounces of water as an evaporative fluid to dissipate the heat through latent transfer.

In one or more embodiments, a wearable electronic device includes an anterior pendant comprising heat generating electronics situated therein. The anterior pendant defines an evaporative fluid reservoir into which evaporative fluid can be placed.

In one or more embodiments, the wearable electronic device also comprises a posterior pendant. A first neck strap couples a first side of the anterior pendant to a first side of the posterior pendant. A second neck strap couples a second side of the anterior pendant to a second side of the posterior pendant.

A wicking element is thermally coupled to an exterior surface of the anterior pendant. In one or more embodiments, the wicking element has a wicking element portion situated within the evaporative fluid reservoir. An evaporative fluid is situated within the evaporative fluid reservoir. The wicking element is configured to draw the evaporative fluid from the evaporative fluid reservoir along the exterior surface of the anterior pendant to cool the exterior surface when the evaporative fluid evaporates to an environment of the wearable electronic device. Advantageously, embodiments of the disclosure provide a wearable electronic device that allows the internal components to operate at higher wattages without compromising reliability or making the wearable electronic device uncomfortable to wear.

To illustrate embodiments of the disclosure, a wearable audio device having two device housings will be used as an explanatory wearable electronic device. However, it should be noted that only one device housing is required for the wicking element to remove thermal energy from heat generating electronics situated therein. The wearable audio device is used for illustrative purposes because it includes an anterior pendant and a posterior pendant that are operable to deliver a stereo image that is aligned with the ears of a wearer. Again, it should be noted that this particular form factor is explanatory only, as the thermal dissipation systems described below could be incorporated into other wearable electronic devices, including those having only a single device housing.

The explanatory wearable electronic device used for illustrative purposes below provides a sleek, slim, and stylish, wearable, audio electronic device that includes an anterior pendant and a posterior pendant that are connected by two minimalist neck straps. It is not always practical—especially when trying to design a stylish and fashionable electronic device—to place the loudspeakers of a wearable audio electronic device beneath the ears of a wearer. In one or more embodiments, positioning a single loudspeaker in an anterior pendant that provides a monaural audio signal output combining a left channel audio signal output and a right channel audio signal output, while simultaneously providing a left channel audio signal output and a right channel audio signal output from a posterior pendant is sufficient to pull the combined stereo image from the posterior pendant toward the anterior pendant to a central location within the wearable electronic device situated at locations corresponding to a wearer's ears. Using a posterior pendant to deliver separate left and right channel audio, while using an anterior pendant to deliver a combined left and right channel audio output provides a rich, enveloping stereo image that sounds as if located right at the user's ears. As noted, this is just one example of a wearable electronic device into which the thermal energy dissipation systems described below can be integrated. Others will be obvious to those of ordinary skill in the art having the benefit of this disclosure.

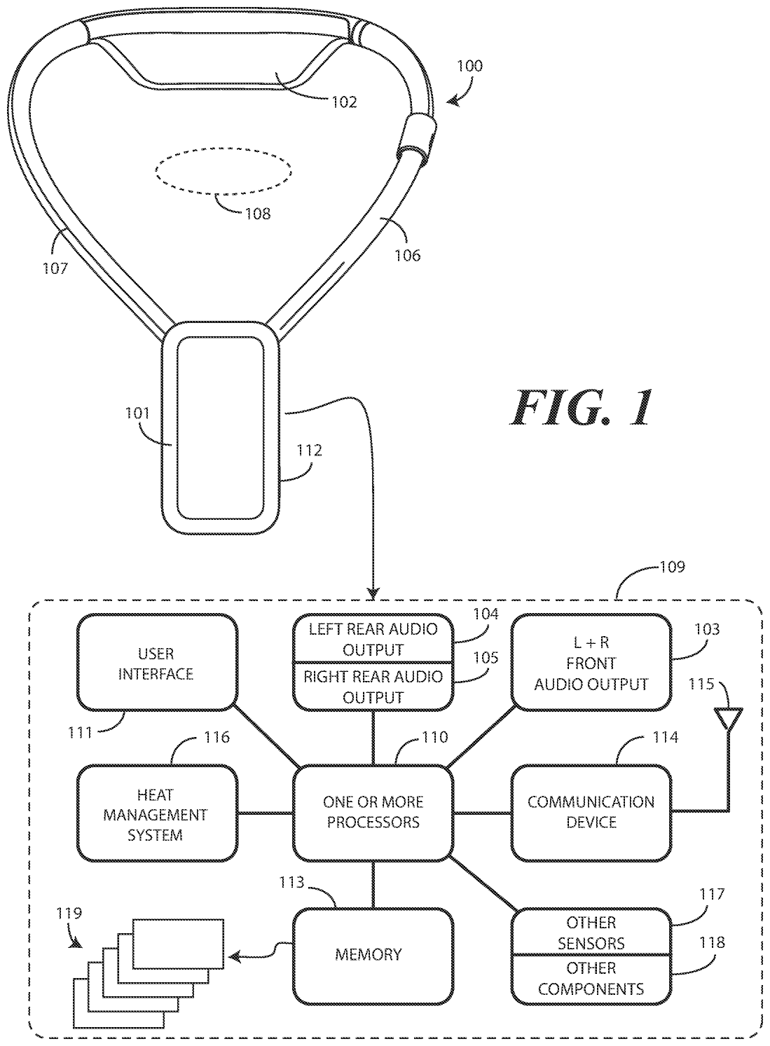

Turning now to FIG. 1, illustrated therein is one explanatory wearable electronic device 100 configured in accordance with one or more embodiments of the disclosure. In one or more embodiments, the wearable electronic device 100 comprises a first device housing coupled to a second device housing by at least one strap. In the illustrative embodiment of FIG. 1, the first device housing consists of an anterior pendant 101, while the second device housing consists of a posterior pendant 102.

In one or more embodiments, each of the anterior pendant 101 and the posterior pendant 102 includes a housing. The housing can include one or more housing portions, such as a first housing portion and a second housing portion. The housing can define one or more major and minor surfaces of the wearable electronic device 100.

In one or more embodiments, the anterior pendant 101 comprises a single channel anterior audio output 103 delivering a combined left channel audio signal and right channel audio signal through a port of the anterior pendant 101. The posterior pendant 102 comprises a first single channel posterior audio output 104 delivering the left channel audio signal through a first port of the posterior pendant 102 and a second single channel posterior audio output 105 delivering the right channel audio signal through a second port of the posterior pendant 102. The combination of the combined left channel audio signal and right channel audio signal from the anterior pendant 101 and the separated left channel audio signal and right channel audio signal from the posterior pendant 102 pull a perceived stereo image toward the anterior pendant 101 to a centralized location within the wearable electronic device 100.

In one or more embodiments, a first neck strap 106 couples a first side of the anterior pendant 101 to a first side of the posterior pendant 102. In one or more embodiments, a second neck strap 107 couples a second side of the anterior pendant 101 to a second side of the posterior pendant 102.

In one or more embodiments, each of the anterior pendant 101 and the posterior pendant 102 includes a housing, while the first neck strap 106 and the second neck strap 107 serve both as a right shoulder strap and left shoulder strap that allow the wearable electronic device 100 to be worn around the neck as well as to provide a conduit for electrical connections and, as will be explained below, a flexible heat pipe passing from the anterior pendant 101 to the posterior pendant 102 or vice versa. While the anterior pendant 101 and posterior pendant 102 can be configured as shown in FIG. 1, other configurations for each housing and/or shoulder strap and/or other mechanical configurations of wearable electronic devices will be obvious to those of ordinary skill in the art having the benefit of this disclosure.

Also illustrated in FIG. 1 is one explanatory block diagram schematic 109 of the wearable electronic device 100. In one or more embodiments, the block diagram schematic 109 can be constructed as multiple printed circuit board assemblies situated within either the housing of the anterior pendant 101, the housing of the posterior pendant 102, the first neck strap 106, the second neck strap 107, or combinations thereof. While this is one embodiment, in another embodiment the electrical connections between the anterior pendant 101 and the posterior pendant 102 are wireless. Where one or more circuit boards are used, the various components and heat generating electronics can be electrically coupled together by conductors or a bus disposed along one or more printed circuit boards, or alternatively by one or more wireless electronic communication circuits. It should be noted that the block diagram schematic 109 includes many components that are optional, but which are included in an effort to demonstrate how varied electronic devices configured in accordance with embodiments of the disclosure can be.

Illustrating by example, in one or more embodiments the wearable electronic device 100 includes a user interface 111. The user interface 111 can include an audio input device, such as a microphone, to receive audio input. The user interface 111 also includes a plurality of audio output devices to deliver audio output, which in this illustrative embodiment include the single channel anterior audio output 103 of the anterior pendant 101 and the first single channel posterior audio output 104 of the posterior pendant 102 and the second single channel posterior audio output 105 of the posterior pendant 102. Each of the single channel anterior audio output 103 of the anterior pendant 101, the first single channel posterior audio output 104 of the posterior pendant 102, and the second single channel posterior audio output 105 of the posterior pendant 102 can consist of a single loudspeaker in one or more embodiments. However, in other embodiments, multiple loudspeakers can be clustered to form each of the single channel anterior audio output 103 of the anterior pendant 101, the first single channel posterior audio output 104 of the posterior pendant 102, and the second single channel posterior audio output 105 of the posterior pendant 102 as well.

In one or more embodiments, the user interface 111 includes a display, which can optionally be configured to be touch sensitive. Where the wearable electronic device 100 is configured to be a companion electronic device to another electronic device, such as a smartphone, with its companion functionality being that of purely an audio output device, a display would be optional, in it is not required for this aural user interaction convention.

Thus, it is to be understood that the block diagram schematic 109 of FIG. 1 is provided for illustrative purposes only and for illustrating components of one wearable electronic device 100 in accordance with embodiments of the disclosure. The block diagram schematic 109 of FIG. 1 is not intended to be a complete schematic diagram of the various components required for a wearable electronic device 100. Therefore, other electronic devices in accordance with embodiments of the disclosure may include various other components not shown in FIG. 1 or may include a combination of two or more components or a division of a particular component into two or more separate components, and still be within the scope of the present disclosure.

The illustrative block diagram schematic 109 of FIG. 1 includes many different components. Embodiments of the disclosure contemplate that the number and arrangement of such components can change depending on the particular application. For example, a wearable electronic device that only includes at least one audio output with no audio input may have fewer, or different, components from a wearable electronic device having both user interface components. Similarly, a wearable electronic device that includes at least one audio output in addition to at least one audio input can include multiple audio inputs, one example of which would be a microphone array. Accordingly, electronic devices configured in accordance with embodiments of the disclosure can include some components that are not shown in FIG. 1, and other components that are shown may not be needed and can therefore be omitted.

As noted above, the user interface 111 can include a display, which may optionally be touch sensitive. In one embodiment, users can deliver user input to the display of such an embodiment by delivering touch input from a finger, stylus, or other objects disposed proximately with the display. In one embodiment, the display is configured as an active-matrix organic light emitting diode (AMOLED) display. However, it should be noted that other types of displays, including liquid crystal displays, suitable for use with the user interface would be obvious to those of ordinary skill in the art having the benefit of this disclosure. Where a display is omitted, a user actuation device 112, such as a button, switch, touch sensitive surface, or other control mechanism can allow a user to operate the wearable electronic device 100.

In one embodiment, the wearable electronic device 100 includes one or more processors 110. In one embodiment, the one or more processors 110 can include an application processor and, optionally, one or more auxiliary processors. One or both of the application processor and/or the auxiliary processor(s) can include one or more processors. One or both of the application processor and/or the auxiliary processor(s) can be a microprocessor, a group of processing components, one or more ASICs, programmable logic, or other type of processing device.

The application processor and/or the auxiliary processor(s) can be operable with the various components of the block diagram schematic 109. Each of the application processor and/or the auxiliary processor(s) can be configured to process and execute executable software code to perform the various functions of the wearable electronic device 100 with which the block diagram schematic 109 operates. A storage device, such as memory 113, can optionally store the executable software code used by the one or more processors 110 during operation.

In this illustrative embodiment, the block diagram schematic 109 also includes a communication circuit 114 that can be configured for wired or wireless communication with one or more other devices or networks. The networks can include a wide area network, a local area network, and/or personal area network. The communication circuit 114 may also utilize wireless technology for communication, such as, but are not limited to, peer-to-peer or ad hoc communications such as HomeRF, Bluetooth and IEEE 802.11-based communications, as well as other forms of wireless communication such as infrared technology. The communication circuit 114 can include wireless communication circuitry, one of a receiver, a transmitter, or transceiver, and one or more antennas 115.

In one embodiment, the one or more processors 110 can be responsible for performing the primary functions of the electronic device with which the block diagram schematic 109 is operational. For example, in one embodiment the one or more processors 110 comprise one or more circuits operable with the user interface 111 to deliver audio output signals in the form of acoustic waves to a user. The source data for generating these acoustic waves could be stored in the memory 113, or alternatively may be received from an external electronic device using the communication circuit 114. The one or more processors 110 can be operable with an audio output device to deliver audio output to a user. The executable software code used by the one or more processors 110 can be configured as one or more modules 119 that are operable with the one or more processors 110. Such modules 119 can store instructions, control algorithms, media content, digital to analog conversion algorithms, sound generation algorithms, and so forth.

In one or more embodiments, the one or more processors 110 operate with, or as, an audio input/processor. The audio input/processor is operable to receive audio input from a source, such as a person, authorized user, plurality of persons within an environment about the wearable electronic device 100, from the environment about the wearable electronic device 100, or combinations thereof. The audio input/processor can include hardware, executable code, and speech monitor executable code in one embodiment. The audio input/processor can be operable with one or both of an audio input device, such as one or more microphones, and/or the audio output devices, each of which can comprise one, or more than one, loudspeaker as previously described.

In one embodiment, the audio input/processor is configured to implement a voice control feature that allows the wearable electronic device 100 to function as a voice assistant device, which is a digital assistant using voice recognition, speech synthesis, and natural language processing to receive audio input comprising a voice command from a source, determine the appropriate response to the voice command, and then deliver the response in the form of audio output in response to receiving the audio input from the source.

Various sensors 117 can be operable with the one or more processors 110. A first example of a sensor that can be included with the various sensors 117 is a touch sensor. The touch sensor can include a capacitive touch sensor, an infrared touch sensor, resistive touch sensors, or another touch-sensitive technology that serves as a user interface 111 for the wearable electronic device 100.

Another example of a sensor 117 is a geo-locator that serves as a location detector. Location of the wearable electronic device 100 can be determined by capturing the location data from a constellation of one or more earth orbiting satellites, or from a network of terrestrial base stations to determine an approximate location.

One or more motion detectors can be configured as an orientation detector that determines an orientation and/or movement of the wearable electronic device 100 in three-dimensional space. Illustrating by example, the orientation detector can include an accelerometer, a multi-axis accelerometer, gyroscopes, or other device to detect device orientation and/or motion of the wearable electronic device 100. Other sensors 117 suitable for inclusion with the wearable electronic device 100 will be obvious to those of ordinary skill in the art having the benefit of this disclosure.

Other components 118 operable with the one or more processors 110 can include output components such as video, audio, and/or mechanical outputs. For example, the output components may include a video output component or auxiliary devices including a cathode ray tube, liquid crystal display, plasma display, incandescent light, fluorescent light, front or rear projection display, and light emitting diode indicator. Other examples of output components include audio output components such as the one or more loudspeakers used for the single channel anterior audio output 103 of the anterior pendant 101, the first single channel posterior audio output 104 of the posterior pendant 102, and the second single channel posterior audio output 105 of the posterior pendant 102, or other alarms and/or buzzers. The other components 118 can also include a mechanical output component such as vibrating or motion-based mechanisms.

In one or more embodiments, the one or more processors 110 can define one or more process engines. One example of such a process engine is the equalizer/delay manager. In one or more embodiments, the equalizer/delay manager is operable to insert a predefined delay between the combined left channel audio signal and right channel audio signal emanating from the single channel anterior audio output 103 of the anterior pendant 101 and each of the left channel audio signal emanating from the first single channel posterior audio output 104 of the posterior pendant 102 and the right channel audio signal emanating from second single channel posterior audio output 105 of the posterior pendant. This predefined delay ensures that audio signals from the posterior pendant 102, which are closer to the user's ears, arrive at the user's ears at the same time or after as those from the anterior pendant 101, which is farther away. In one or more embodiments, the equalizer/delay manager can also adjust the relative volume levels of sound emanating the combined left channel audio signal and right channel audio signal emanating from the single channel anterior audio output 103 of the anterior pendant 101 and each of the left channel audio signal emanating from the first single channel posterior audio output 104 of the posterior pendant 102 and the right channel audio signal emanating from second single channel posterior audio output 105 of the posterior pendant to affect the overall user experience as well.

Each process engine can be a component of the one or more processors 110, operable with the one or more processors 110, defined by the one or more processors 110, and/or integrated into the one or more processors 110. Other configurations for these process engines, including as software or firmware modules operable on the one or more processors 110, will be obvious to those of ordinary skill in the art having the benefit of this disclosure.

These various hardware components, in operation, can generate a lot of heat. Illustrating by example, the one or more processors 110, which are situated within the anterior pendant 101 in one or more embodiments, constitute heat generating electronics that generate heat when performing the operations of the wearable electronic device 100. Accordingly, in one or more embodiments a heat management system 116 is included to help evaporatively transfer thermal energy from the anterior pendant 101 to an environment of the wearable electronic device 100. Where the posterior pendant 102 includes heat generating electronics, another heat management system can be included to cool the posterior pendant 102 in the same way.

In one or more embodiments, the heat management system 116 comprises a reservoir of evaporative fluid and a wicking element engaging the reservoir of evaporative fluid. The wicking element can then span a major surface of the device housing in which it is situated. Thus, if the anterior pendant 101 has the reservoir of evaporative fluid, the wicking element can span a major surface of the anterior pendant 101. Similarly, of the posterior pendant 102 has the reservoir of evaporative fluid, the wicking element can engage this reservoir of evaporative fluid and span a major surface of the posterior pendant 102. Of course, both the anterior pendant 101 and the posterior pendant 102 can include reservoir of evaporative fluids and wicking elements in other embodiments.

In one or more embodiments, a heat spreader can be thermally coupled between the heat generating electronics and the device housing in which the heat generating electronics are situated. Illustrating by example, if the anterior pendant 101 includes the heat generating electronics, in one or more embodiments a heat spreader is positioned between the heat generating electronics and the device housing of the anterior pendant 101 to assist in transferring thermal energy from the heat generating electronics to the device housing. The wicking element, spanning the device housing, can then help transfer the thermal energy to the environment via evaporative cooling. The result is a significant reduction in the temperature of the device housing, which allows for a higher performance capability by the one or more processors 110 and other heat generating electronics of the block diagram schematic 109.

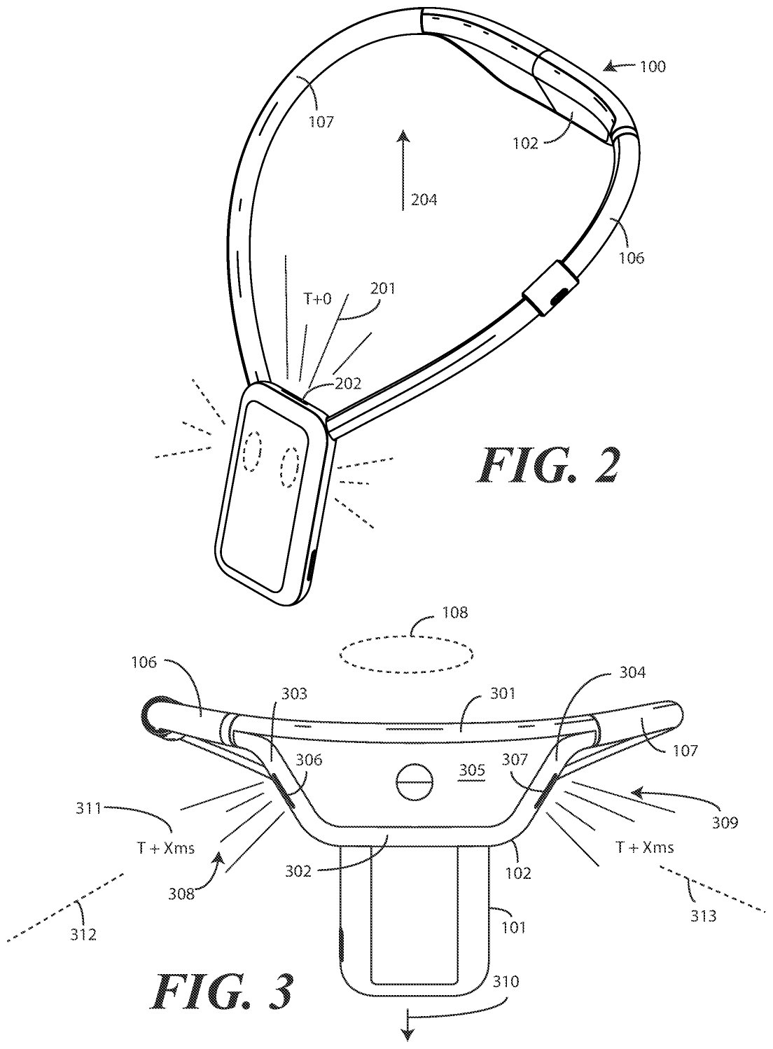

As noted above, in one or more embodiments the electronic device 100 of FIG. 1 is configured as a wearable audio device. To illustrate how such an explanatory embodiment can function, and turning now to FIGS. 2-3, illustrated therein is the explanatory electronic device 100 of FIG. 1 delivering audio output signals that combine to move a stereo image from a location closer to the posterior pendant 102 to one farther from the posterior pendant 102, closer to the anterior pendant 101, and situated vertically within a columnar boundary defined by the anterior pendant 101, the posterior pendant 102, the first neck strap 106, and the second neck strap 107.

As shown in FIG. 2, the single channel anterior audio output (103) of the anterior pendant 101 delivers a combined left channel audio signal and right channel audio signal output 201 through a port 202 of the anterior pendant 101. In this illustrative embodiment, the port 202 of the anterior pendant 101 is situated along an upper edge 301 of the anterior pendant 101. This results in the combined left channel audio signal and right channel audio signal output 201 being directed toward a cranial side 204 of the wearable electronic device 100.

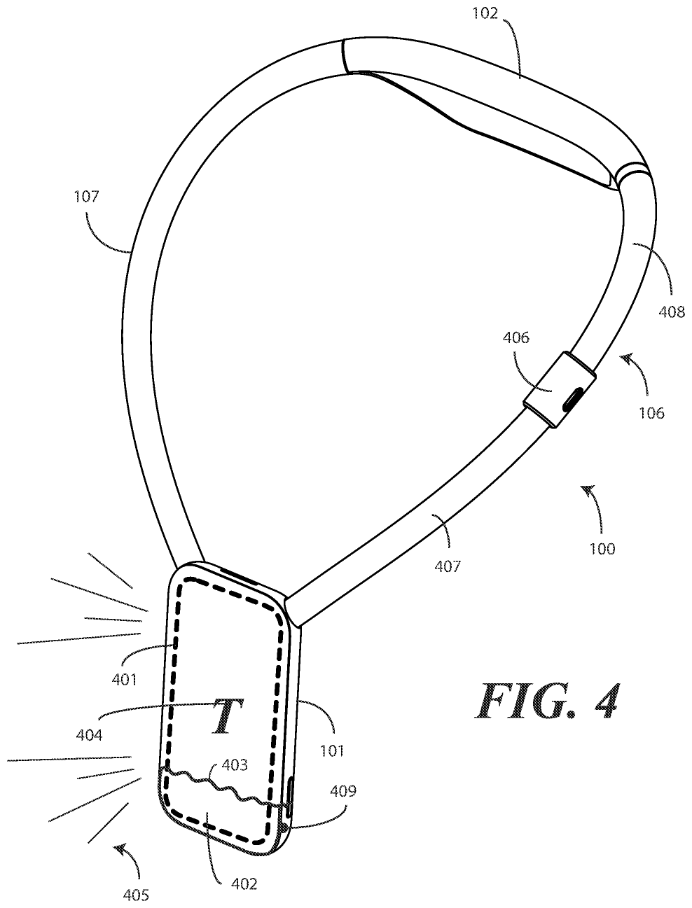

As shown in FIG. 3, the posterior pendant 102 comprises an upper edge 301, a lower edge 302, a first side edge 303, and a second side edge 304. In one or more embodiments, the first side edge 303 and the second side edge 304 taper inward as they extend from the upper edge 301 to the lower edge 302. In so doing, the upper edge 301, which defines a first end of the posterior pendant 102, the lower edge 302, which defines a base of the posterior pendant 102, define a caudally facing (when the wearable electronic device 100 is worn as shown in FIGS. 3-4 below) frustoconical posterior pendant major surface 305. As used herein, “frustoconical” takes its ordinary meaning of the shape of a frustum or cone with its pointed end cut off by a plane running substantially parallel to its base. In this vein, the caudally facing frustoconical posterior pendant major surface is wider at the top than at the bottom with the upper edge 301 being oriented substantially parallel with the lower edge 302, and with the first side edge 303 and second side edge 304 tapering inward as they extend downward (caudally) from the upper edge 301.

In one or more embodiments, the first port 306 of the posterior pendant 102 is situated on the first side edge 303, while the second port 307 of the posterior pendant 102 is situated on the second side edge 304. This arrangement, counterintuitively, causes the left channel audio signal output 308 and the right channel audio signal output 309 to be directed downward, i.e., toward a caudal side 310 of the wearable electronic device 100 and away from each other. This orientation results in central axes 312,313 of the first port 306 of the posterior pendant 102 and the second port 307 of the posterior pendant 102, which pass from an interior of the posterior pendant 102 to an exterior of the posterior pendant 102, extending downward from the upper edge 301 of the posterior pendant 102 and away from each other. Thus, the left channel audio signal output 308 is delivered downward and away from both the posterior pendant 102 and the right channel audio signal output 309, while the right channel audio signal output 309 is delivered downward and away from both the posterior pendant 102 and the left channel audio signal output 308.

While perhaps initially counterintuitive, delivering the left channel audio signal output 308 and right channel audio signal output 309 downward and away from the posterior pendant 102 at roughly forty-five degree angles maximizes the aural separation of each channel, thereby improving the robustness and richness of the stereo image 108 resulting from the combination of the combined left channel audio signal output and right channel audio signal output 201 from the port 202 in the anterior pendant 101 and the left channel audio signal output 308 and the right channel audio signal output 309 from the first port 306 and second port 307 of the posterior pendant 102.

As shown in FIGS. 2-3, in one or more embodiments when the wearable electronic device 100 is worn the anterior pendant 101 is farther from the user's ears than is the posterior pendant 102. Consequently, the port 202 of the anterior pendant 101 is farther from the user's ears than either the first port 306 of the posterior pendant 102 or the second port 307 of the posterior pendant 102. Accordingly, it takes more time for the the combined left channel audio signal and right channel audio signal output 201 to reach the user's ears than either the left channel audio signal output 308 or right channel audio signal output 309.

To compensate, in one or more embodiments one or more processors (110) of the wearable electronic device 100 insert a predefined delay 311 between the combined left channel audio signal and right channel audio signal output 201 emanating from the single channel anterior audio output (103) and each of the left channel audio signal output 308 and right channel audio signal output 309 emanating from the first single channel posterior audio output (104) and the second single channel posterior audio output (105), respectively. Since sound travels at 1100 feet per second, which is roughly one millisecond per foot, in one or more embodiments the predefined delay 311 is about one millisecond. Embodiments of the disclosure contemplate that delays over three milliseconds will affect the desirability of the stereo image 108. Accordingly, in one or more embodiments the predefined delay 311 is less than three milliseconds. As previously described, the predefined delay 311 can be user definable in one or more embodiments.

Regardless of whether the components of the electronic device 100 are delivering audio as described above with reference to FIGS. 2-3, or are performing other functions, in one or more embodiments they generate heat when performing the functions of the electronic device 100. In one or more embodiments, the electronic components situated in the anterior pendant 101 generate more heat than do the components (where there are components) situated in the posterior pendant 102. Turning now to FIG. 4, illustrated therein is one explanatory system with which the heat generated by the heat generating electronics situated in the anterior pendant 101 can be transferred to the posterior pendant 102 for dissipation to the environment through the device housing of the posterior pendant 102.

As shown in FIG. 4, the electronic device 100 includes a first device housing, shown illustratively as the anterior pendant 101, and a second device housing, shown illustratively as the posterior pendant 102. Heat generating electronics, which could be any of the components described above with reference to FIG. 1, including the one or more processors (110), the communication circuit (114), the memory (113), the sensors (117), or other components (118), are situated within the first device housing defined by the anterior pendant 101. In one or more embodiments, electronic components are situated in the posterior pendant 102 as well. However, in one or more embodiments the electronic components situated in the anterior pendant 101 generate more heat than do the components situated in the posterior pendant 102.

In one or more embodiments, the anterior pendant 101 includes a reservoir of evaporative fluid 402 with evaporative fluid 403 situated therein. A fluid reservoir replenishment port 409 is included in the device housing of the anterior pendant 101 to allow the evaporative fluid 403 to be replenished when depleted from the reservoir of evaporative fluid 402.

A wicking element 401 has a portion thereof inserted into the reservoir of evaporative fluid 402 such that the portion of the wicking element 401 situated in the reservoir of evaporative fluid 402 engages the evaporative fluid 403. The wicking element 401 draws the evaporative fluid 403 from the reservoir of evaporative fluid 402 through the wicking element 401 and along a surface of the anterior pendant to remove thermal energy 404 from the heat generating electronics via evaporation.

Various fluids can be used as the evaporative fluid 403. Illustrating by example, quickly evaporating liquids such as isopropyl alcohol can be used as the evaporative fluid 403 in one or more embodiments. However, the faster the evaporative fluid 403 evaporates, the more frequently it needs to be replenished. Accordingly, in one or more embodiments the evaporative fluid 403 is simply water.

The wicking element 401 can be manufactured from various organic and inorganic materials. In one or more embodiments, the wicking element 401 comprises a cotton gauze material that draws water from the reservoir of evaporative fluid 402 along the length of the wicking element 401.

In this illustrative embodiment, the wicking element 401 is positioned along a major surface of the anterior pendant 101. As shown, in this illustrative embodiment the wicking element abuts and spans the exterior of the major surface.

In one or more embodiments, the wicking element 401 transfers thermal energy 404 from the heat generating electronics through the device housing of the anterior pendant 101. While the posterior pendant 102 can include heat generating electronics as well, in the illustrative embodiment of FIG. 4 the other heat generating electronics situated in the posterior pendant 102 generate less heat than to the heat generating electronics situated within the anterior pendant 101. Said differently, in one or more embodiments when other heat generating electronics are situated within the second device housing defined by the posterior pendant 102, the heat generating electronics situated within the first device housing defined by the anterior pendant 101 generate more heat than the other heat generating electronics situated in the posterior pendant 102. Consequently, transferring the thermal energy 404 through the device housing of the anterior pendant 101 not only cools the anterior pendant 101, but allows that thermal energy 404 to be dissipated 405 through the device housing to the environment.

In this illustrative embodiment, the first neck strap 106 includes a first first neck strap portion 407 and a second first neck strap portion 408. A coupler 406 attaches the first first neck strap portion 407 to the second first neck strap portion 408. The inclusion of the coupler 406 allows a wearer to separate the first neck strap 106, place the wearable electronic device 100 around their neck, and then reattach the first neck strap 106 to don the wearable electronic device 100.

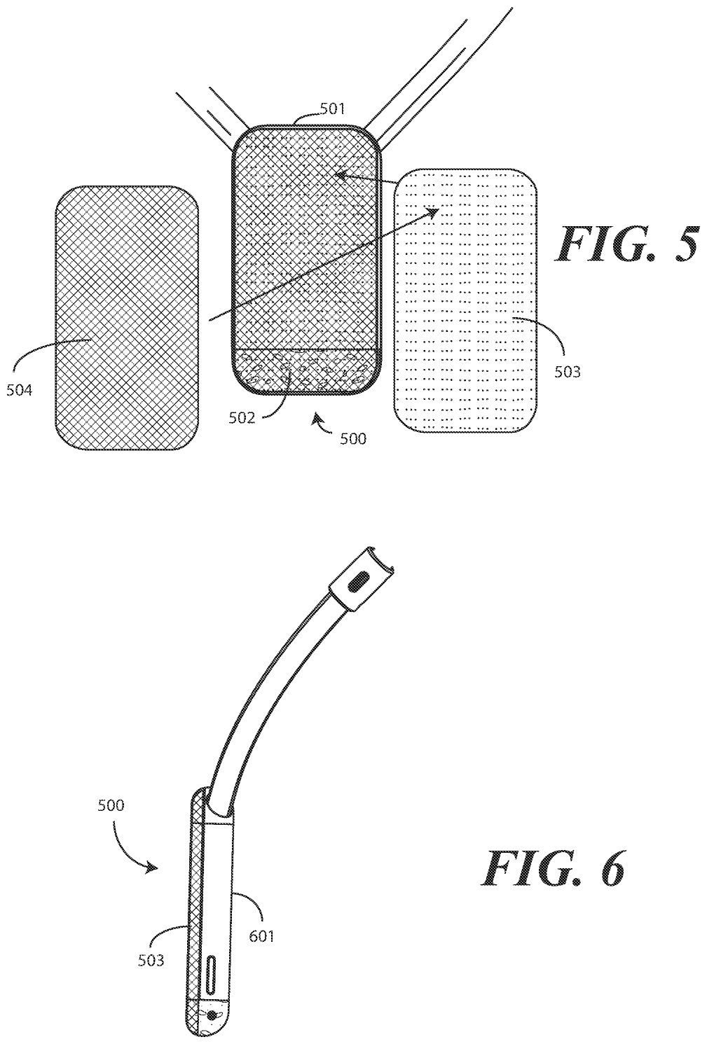

Turning now to FIG. 5, illustrated therein is another wearable electronic device 500 configured in accordance with one or more embodiments of the disclosure. As shown, the wearable electronic device includes a device housing 501 with heat generating electronics situated therein. At the base of the device housing 501 is a reservoir of evaporative fluid 502. A wicking element 503 engages the reservoir of evaporative fluid 502 to draw evaporative fluid from the reservoir of evaporative fluid through the wicking element 503 to remove thermal energy from the heat generating electronics. The wicking element 503 is positioned upon a major surface of the device housing 501 and spans and abuts the exterior of the major surface.

A wicking element retention device 504 then retains the wicking element 503 against the major surface of the device housing 501. In one or more embodiments, the wicking element retention device 504 is perforated so that evaporative fluid can evaporate from the wicking element 503 through the perforations to the environment around the wearable electronic device 500.

Turning now to the side view of the wearable electronic device 500 shown in FIG. 6, in one or more embodiments the device housing 501 defines a chest support surface 601 which is situated on an opposite side of the device housing 501 from the major surface to against which the wicking element retention device retains the wicking element 503. This positioning allows the thermal energy to be removed away from a wearer when the chest support surface 601 is positioned against the wearer's chest.

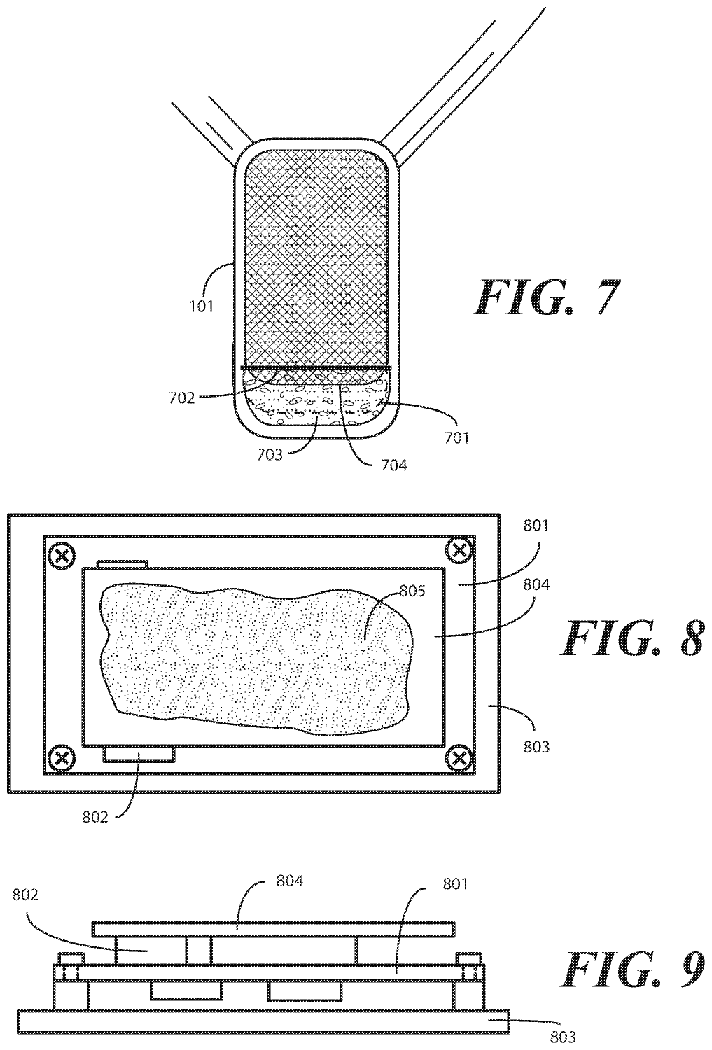

Turning now to FIGS. 7-9, illustrated therein is one explanatory architecture by which the general system of FIG. 4 can be achieved. FIG. 7 illustrates the anterior pendant 101 of FIG. 4, while FIGS. 8-9 illustrate components situated within the anterior pendant 101. FIG. 8 illustrates these components in plan view, while FIG. 9 illustrates these components in a side elevation view.

In one or more embodiments, a printed circuit board 801 supports the heat generating electronics 802, which are shown as integrated circuit components. In this illustrative example, the printed circuit board 801 is suspended from a device housing 803 defining a sidewall of the anterior pendant 101 by a plurality of bosses. A plurality of screws fixedly couples the printed circuit board 801 to the bosses, thereby preventing the printed circuit board 801 from moving relative to the device housing.

While the heat generating electronics 802 can abut the device housing 803 of the anterior pendant 101, in this illustrative embodiment a heat spreader 804 is situated in the device housing 803 defining the anterior pendant 101. The heat spreader 804 thermally couples the device housing 803 to the heat generating electronics 802. In this illustrative embodiment, the bottoms of the heat generating electronics 802 are coupled to the printed circuit board 801, while the heat spreader 804 is coupled to the tops of the heat generating electronics 802. This results in the heat spreader 804 and the printed circuit board 801 being physically separated by the heat generating electronics 802.

Where the heat spreader 804 is used, a thermal interface material 805 may be positioned between the heat spreader 804 and the heat generating electronics 802. One example of such a thermal interface material is thermally conductive grease. Other examples of thermal interface materials suitable to increase the thermal coupling between the heat spreader 804 and the heat generating electronics 802 will be obvious to those of ordinary skill in the art having the benefit of this disclosure. The thermal interface material 805 may also be positioned between the heat spreader 804 and the device housing 803 of the anterior pendant 101 as well.

The heat spreader 804 can be manufactured from a variety of thermally conductive materials. In one or more embodiments, the heat spreader 804 is a large section of thermally conductive material coupled to the device housing 803 of the anterior pendant 101. Illustrating by example, the heat spreader 804 may be a section of copper, aluminum, or other metal material. In other embodiments, the heat spreader 804 is manufactured from a carbon-based film and is attached to the device housing 803 of the anterior pendant 101 by a thermally conductive adhesive. Other materials suitable for making the heat spreader 804 will be obvious to those of ordinary skill in the art having the benefit of this disclosure.

In still other embodiments, the heat spreader 804 comprises a vapor chamber. The vapor chamber collects the thermal energy generated by the heat generating electronics 802 and spreads it along a surface of the device housing 803 of the anterior pendant 101 for dispersion to the environment via evaporation of the evaporative fluid through a wicking element positioned against the surface of the device housing 803 of the anterior pendant 101. Effectively, the vapor chamber defines a planar heat pipe that spreads the thermal energy received from the heat generating electronics 802 in two dimensions. This thermal energy vaporizes a liquid in an evaporator wick situated within the vapor chamber. The now vaporized liquid condenses on the inner surfaces of the vapor chamber, where the thermal energy dissipates via convection to the device housing 803 of the anterior pendant 101. Capillary action then draws the liquid back to the evaporator wick.

Regardless of form, the function of the heat spreader 804 situated within the device housing 803 of the anterior pendant 101 is to dissipate thermal energy through the device housing 803 of the anterior pendant 101 where evaporation of the evaporative fluid from the wicking element 701. In this illustrative embodiment, the wicking element 701 passes along a major surface of the device housing 803 of the anterior pendant 101 to an aperture 702 defined as a slit. The wicking element 701 then passes into the slit to an interior portion of the device housing 803 defining reservoir of evaporative fluid 703 of the anterior pendant 101. The wicking element 701 is retained against the major surface of the device housing 803 of the anterior pendant 101 by a wicking element retention device 704 as previously described.

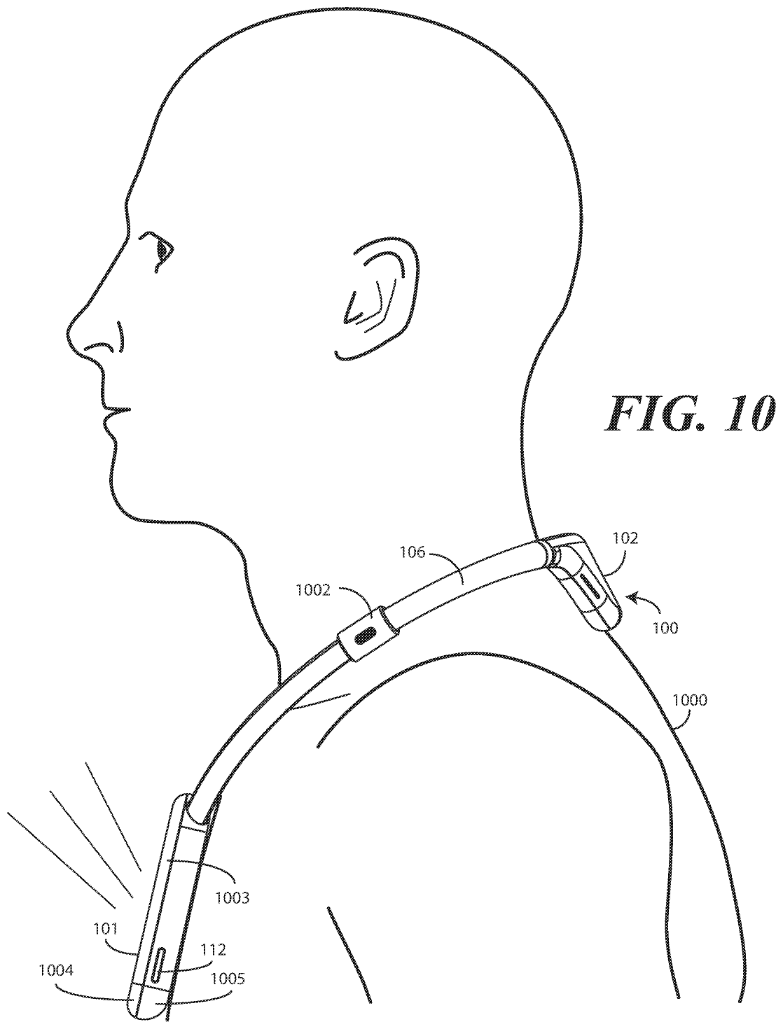

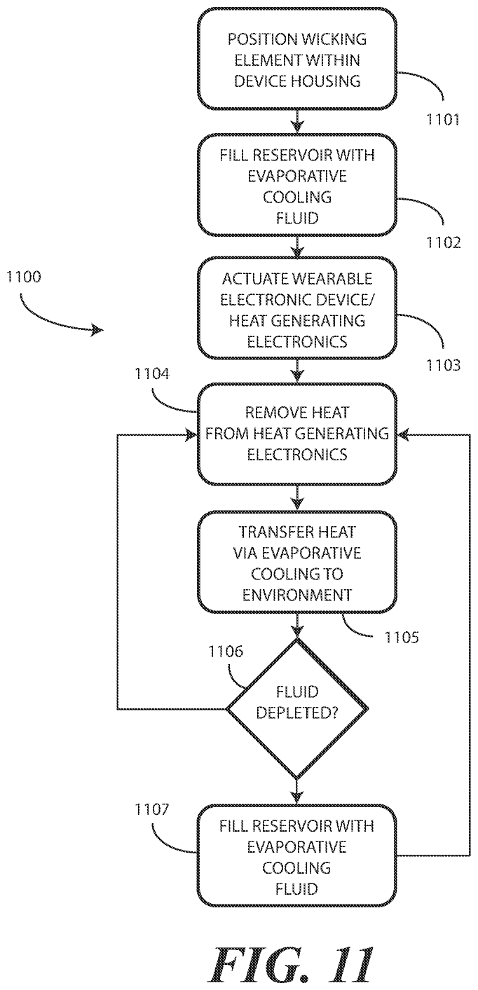

Turning now to FIG. 10, illustrated therein is a user 1000 wearing a wearable electronic device 100 configured in one or more embodiments of the disclosure. As previously described, the wearable electronic device 100 includes an anterior pendant 101 and a posterior pendant 102. In this illustrative embodiment the anterior pendant 101 is generally rectangular in shape and situates at the anterior portion of the user's torso by sitting flush against the user's chest with the first port of the anterior pendant 101 situating beneath the user's chin in front of the user's ears. The posterior pendant 102 takes the shape of an inverted frustoconical quadrilateral and situates on the posterior portion of the user's torso by sitting flush against the user's shoulders behind the neck and behind the user's ears.

A right shoulder strap (107) passes across the user's right shoulder and couples the right sides of the anterior pendant 101 and the posterior pendant 102 together. Likewise, a left shoulder strap 106 passes across the user's left shoulder and couples the left sides of the anterior pendant 101 and the posterior pendant 102 together.

In this illustrative embodiment, each of the right shoulder strap (107) and the left shoulder strap 106 are circular in cross section and exit from the top of the posterior pendant 102 as extensions from the widest edge of the inverted frustoconical quadrilateral and then enter the upper corners of the rectangle defining the anterior pendant 101. An optional decoupling clasp 1002 can be used to open the left shoulder strap 106 so that the wearable electronic device 100 need not be passed over the user's head to be donned. While shown positioned along the left shoulder strap 106 in FIG. 10, the optional decoupling clasp 1002 could be placed on the right shoulder strap (107) as well.

In this illustrative embodiment, a user actuation device 112, shown as a button in FIG. is placed on a minor surface of the anterior pendant 101. The user actuation device 112 can be used to turn the wearable electronic device 100 ON, turn it OFF, and to perform other control operations as well. For example, a long press of the user actuation device 112 when the wearable electronic device 100 is OFF may turn the same ON, while short presses of the user actuation device 112 while the wearable electronic device 100 is ON may perform certain control operations such as track advance, pausing, playing, and so forth. A long press of the user actuation device 112 when the wearable electronic device 100 is ON may turn the wearable electronic device 100 OFF.

The illustrative wearable electronic device 100 of FIG. 10 includes a plurality of audio outputs. In one or more embodiments, these comprise a left channel audio signal output situated at a first end of the posterior pendant 102 and a right channel audio signal output situated at a second end of the posterior pendant 102. In the illustrative embodiment of FIG. 10, the left channel audio signal output and the right channel audio signal output are separated from each other by the body of the posterior pendant 102. On the anterior pendant 101, a single combined left channel and right channel audio signal output is situated at a cranial edge of the anterior pendant 101.

The base of the posterior pendant 102, and the second end of the posterior pendant define a caudally facing frustoconical posterior pendant major surface. This results in central axes of the left channel audio signal output and the right channel audio signal output being directed downward and away from the user's ears.

A wicking element 1003 is thermally coupled to an exterior surface of the anterior pendant 101. The wicking element 1003 includes a wicking element portion 1004 that is situated within an evaporative fluid reservoir 1005 defined by the device housing of the anterior pendant 101 and containing an evaporative fluid situated therein. The wicking element 1003 is configured to draw the evaporative fluid from the evaporative fluid reservoir 1005 along the exterior surface of the anterior pendant 101 to cool the exterior surface when the evaporative fluid evaporates to an environment of the wearable electronic device 100.

Turning now to FIG. 11, illustrated therein is one explanatory method 1100 of removing thermal energy from a device housing of a wearable electronic device via evaporation of an evaporative fluid contained in an evaporative fluid reservoir through a wicking element in accordance with one or more embodiments of the disclosure. The method 1100 of FIG. 11 removes thermal energy from a device housing of the wearable electronic device and transfers the thermal energy to an environment of the wearable electronic device.

Beginning at step 1101, a wicking element is positioned against a surface of the device housing of the wearable electronic device with at least a portion of the wicking element extending into an evaporative fluid reservoir. Step 1101 can optionally comprise using a wicking element retention device to retain the wicking element against the surface of the device housing. At step 1102, the evaporative fluid reservoir is filled with an evaporative fluid, one example of which is water. In one or more embodiments, filling the evaporative fluid reservoir with the evaporative fluid causes the portion of the wicking element situated within the evaporative fluid reservoir to engage the evaporative fluid.

At step 1103, the wearable electronic device is actuated. In one or more embodiments, the device housing of the wearable electronic device is configured as an anterior pendant and includes heat generating electronics. Accordingly, the actuation occurring at step 1103 causes the heat generating electronics to generate heat in addition to making the wearable electronic device operational.

Step 1104 comprises transferring the thermal energy from the heat generating electronics situated within the device housing to an interior surface of a sidewall of the device housing. In one or more embodiments, the transfer occurring at step 1104 comprises transferring the thermal energy from a heat spreader to the interior surface of the sidewall of the device housing. As previously described, a thermal grease can be positioned between one or both of the heat generating electronics and the heat spreader and/or the heat spreader and the sidewall to increase thermal coupling between the heat generating electronics and the sidewall.

At step 1105, the thermal energy is transferred via evaporative cooling to an environment of the electronic device. In one or more embodiments, step 1105 comprises drawing the evaporative fluid from the evaporative fluid reservoir through the wicking element abutting the exterior surface of the sidewall of the device housing and cooling the sidewall by allowing the evaporative fluid to evaporate to the environment of the electronic device.

Decision 1106 then determines whether the evaporative fluid has been depleted from the evaporative fluid reservoir. Where it has, the method 1100 comprises refilling the evaporative fluid reservoir at step 1107. In one or more embodiments, step 1107 comprises refilling the evaporative fluid reservoir upon determining the evaporative fluid reservoir is depleted while the heat generating electronics are generating heat. Otherwise, the method 1100 returns to step 1104 where additional thermal energy is removed from the device housing of the electronic device.

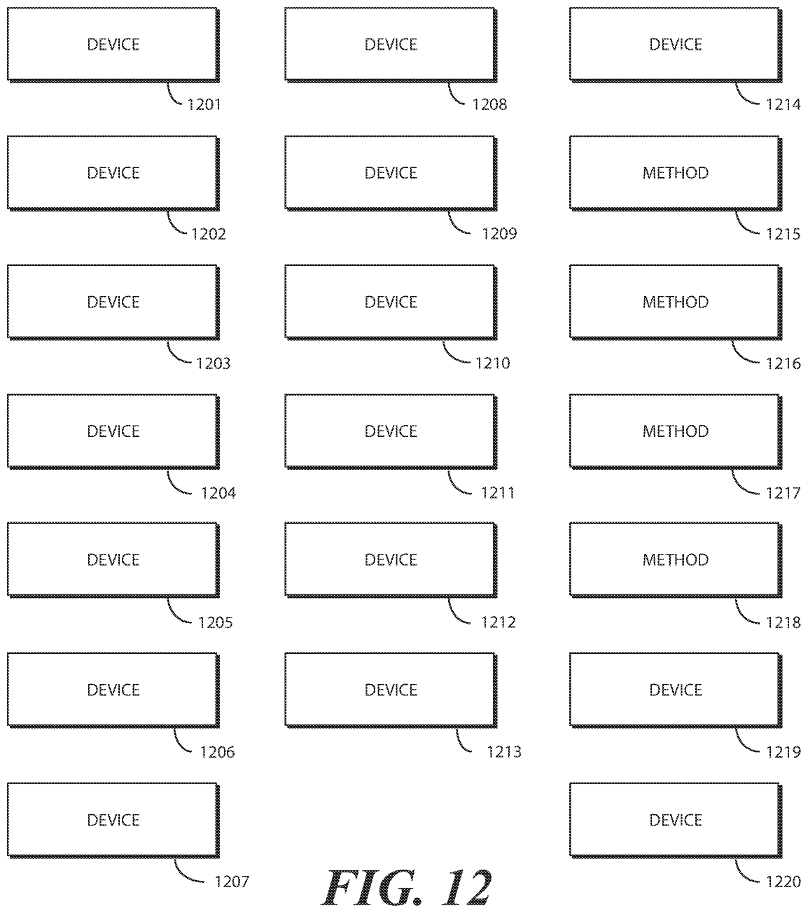

Turning now to FIG. 12, illustrated therein are various embodiments of the disclosure. The embodiments of FIG. 12 are shown as labeled boxes in FIG. 12 due to the fact that the individual components of these embodiments have been illustrated in detail in FIGS. 1-11, which precede FIG. 12. Accordingly, since these items have previously been illustrated and described, their repeated illustration is no longer essential for a proper understanding of these embodiments. Thus, the embodiments are shown as labeled boxes.

At 1201, a wearable electronic device comprises a device housing and heat generating electronics situated within the device housing. At 1201, the device housing comprises a reservoir of evaporative fluid.

At 1201, the wearable electronic device also comprises a wicking element engaging the reservoir of evaporative fluid. At 1201, the wicking element draws the evaporative fluid from the reservoir of evaporative fluid through the wicking element to remove thermal energy from the heat generating electronics.

At 1202, the device housing of 1201 comprises an evaporative fluid reservoir replenishment port. At 1203, the device housing of 1202 defines a major surface. At 1203, the wicking element abuts and spans an exterior of the major surface. At 1204, the device housing of 1203 defines a chest support surface on an opposite side of the device housing from the major surface.

At 1205, the wearable electronic device of 1204 further comprises a wicking element retention device retaining the wicking element abutted against the major surface. At 1206, the wicking element retention device of 1205 is perforated.

At 1207, the wearable electronic device of 1204 further comprises another device housing coupled to the device housing by at least one neck strap. At 1208, the wearable electronic device of 1207 further comprises other heat generating electronics situated within the other device housing. At 1208, the heat generating electronics situated within the device housing generate more heat than the other heat generating electronics.

At 1209, the device housing of 1207 comprises an anterior pendant. At 1209, the other device housing comprises a posterior pendant. At 1209, the at least one neck strap comprises a first neck strap coupling a first side of the anterior pendant to a first side of the posterior pendant and a second neck strap coupling a second side of the anterior pendant to a second side of the posterior pendant.

At 1210, the second neck strap of 1209 comprises a first second neck strap portion and a second second neck strap portion. At 1210, the wearable electronic device further comprises a coupler to attach the first second neck strap portion and the second second neck strap portion together.

At 1211, the wearable electronic device of 1205 further comprises a printed circuit board supporting the heat generating electronics. At 1211, the wearable electronic device comprises a heat spreader situated in the device housing and thermally coupling the heat generating electronics to an interior of the major surface.

At 1212, the wearable electronic device of 1211 further comprises thermal grease positioned between the heat spreader and the heat generating electronics. At 1213, the heat spreader of 1211 comprises a vapor chamber. At 1214, the printed circuit board and the heat spreader of 1211 are physically separated.

At 1215, a method of cooling a wearable electronic device comprises transferring thermal energy from heat generating electronic electronics situated within a device housing to an interior surface of sidewall of the device housing. At 1215, the method comprises drawing evaporative fluid from an evaporative fluid reservoir through a wicking element abutting an exterior surface of the sidewall of the device housing. At 1215, the method comprises cooling the sidewall by allowing the evaporative fluid to evaporate to an environment of the wearable electronic device.

At 1216, the method of 1215 further comprises filling the evaporative fluid reservoir with evaporative fluid. At 1217, the method of 1215 further comprises refilling the evaporative fluid reservoir upon determining the evaporative fluid reservoir is depleted while the heat generating electronics are generating heat. At 1218, the transfer of the thermal energy of 1215 to the interior surface of the sidewall of the device housing comprises transferring the thermal energy from a heat spreader to the interior surface of the sidewall of the device housing.

At 1219, a wearable electronic device comprises an anterior pendant comprising heat generating electronics situated therein. At 1219, the anterior pendant defines an evaporative fluid reservoir.

At 1219, the wearable electronic device comprises a posterior pendant. At 1219, the wearable electronic device comprises a first neck strap coupling a first side of the anterior pendant to a first side of the posterior pendant and a second neck strap coupling a second side of the anterior pendant to a second side of the posterior pendant.

At 1219, the wearable electronic device comprises a wicking element. At 1219, the wicking element is thermally coupled to an exterior surface of the anterior pendant. At 1219, the wicking element has a wicking element portion situated within the evaporative fluid reservoir.

At 1220, the wearable electronic device of 1219 further comprises evaporative fluid situated within the evaporative fluid reservoir. At 1220, the wicking element is configured to draw the evaporative fluid from the evaporative fluid reservoir along the exterior surface of the anterior pendant to cool the exterior surface when the evaporative fluid evaporates to an environment of the wearable electronic device.

In the foregoing specification, specific embodiments of the present disclosure have been described. However, one of ordinary skill in the art appreciates that various modifications and changes can be made without departing from the scope of the present disclosure as set forth in the claims below. Thus, while preferred embodiments of the disclosure have been illustrated and described, it is clear that the disclosure is not so limited. Numerous modifications, changes, variations, substitutions, and equivalents will occur to those skilled in the art without departing from the spirit and scope of the present disclosure as defined by the following claims.

Accordingly, the specification and figures are to be regarded in an illustrative rather than a restrictive sense, and all such modifications are intended to be included within the scope of present disclosure. The benefits, advantages, solutions to problems, and any element(s) that may cause any benefit, advantage, or solution to occur or become more pronounced are not to be construed as a critical, required, or essential features or elements of any or all the claims. The disclosure is defined solely by the appended claims including any amendments made during the pendency of this application and all equivalents of those claims as issued.

What is claimed is:

1. A wearable electronic device, comprising:
a device housing;
heat generating electronics situated within the device housing;
a reservoir of evaporative fluid; and
a wicking element engaging the reservoir of evaporative fluid to draw the evaporative fluid from the reservoir of evaporative fluid through the wicking element to remove thermal energy from the heat generating electronics.

2. The wearable electronic device of claim 1, the device housing comprising an evaporative fluid reservoir replenishment port.

3. The wearable electronic device of claim 2, wherein:
the device housing defines a major surface; and
the wicking element abuts and spans an exterior of the major surface.

4. The wearable electronic device of claim 3, wherein the device housing defines a chest support surface on an opposite side of the device housing from the major surface.

5. The wearable electronic device of claim 4, further comprising a wicking element retention device retaining the wicking element abutted against the major surface.

6. The wearable electronic device of claim 5, wherein the wicking element retention device is perforated.

7. The wearable electronic device of claim 4, further comprising another device housing coupled to the device housing by at least one neck strap.

8. The wearable electronic device of claim 7, further comprising other heat generating electronics situated within the another device housing, wherein the heat generating electronics situated within the device housing generate more heat than the other heat generating electronics.

9. The wearable electronic device of claim 7, wherein:
the device housing comprises an anterior pendant;
the another device housing comprises a posterior pendant; and
the at least one neck strap comprises a first neck strap coupling a first side of the anterior pendant to a first side of the posterior pendant and a second neck strap coupling a second side of the anterior pendant to a second side of the posterior pendant.

10. The wearable electronic device of claim 9, wherein the second neck strap comprises a first second neck strap portion and a second second neck strap portion, further comprising a coupler to attach the first second neck strap portion and the second second neck strap portion together.

11. The wearable electronic device of claim 5, further comprising:
a printed circuit board supporting the heat generating electronics; and
a heat spreader situated in the device housing and thermally coupling the heat generating electronics to an interior of the major surface.

12. The wearable electronic device of claim 11, further comprising thermal grease positioned between the heat spreader and the heat generating electronics.

13. The wearable electronic device of claim 11, wherein the heat spreader comprises a vapor chamber.

14. The wearable electronic device of claim 11, wherein the printed circuit board and the heat spreader are physically separated.

15. A method of cooling a wearable electronic device, the method comprising:
transferring thermal energy from heat generating electronic electronics situated within a device housing to an interior surface of sidewall of the device housing;
drawing evaporative fluid from an evaporative fluid reservoir through a wicking element abutting an exterior surface of the sidewall of the device housing; and
cooling the sidewall by allowing the evaporative fluid to evaporate to an environment of the wearable electronic device.

16. The method of claim 15, further comprising filling the evaporative fluid reservoir with evaporative fluid.

17. The method of claim 15, further comprising refilling the evaporative fluid reservoir upon determining the evaporative fluid reservoir is depleted while the heat generating electronics are generating heat.

18. The method of claim 15, wherein the transferring the thermal energy to the interior surface of the sidewall of the device housing comprises transferring the thermal energy from a heat spreader to the interior surface of the sidewall of the device housing.

19. A wearable electronic device, comprising:
an anterior pendant comprising heat generating electronics situated therein and defining an evaporative fluid reservoir;
a posterior pendant;
a first neck strap coupling a first side of the anterior pendant to a first side of the posterior pendant;
a second neck strap coupling a second side of the anterior pendant to a second side of the posterior pendant; and
a wicking element thermally coupled to an exterior surface of the anterior pendant and having a wicking element portion situated within the evaporative fluid reservoir.

20. The wearable electronic device of claim 19, further comprising:
evaporative fluid situated within the evaporative fluid reservoir;
wherein the wicking element is configured to draw the evaporative fluid from the evaporative fluid reservoir along the exterior surface of the anterior pendant to cool the exterior surface when the evaporative fluid evaporates to an environment of the wearable electronic device.
